(19) United States
(12) Patent Application Publication
(10) Pub. No.: US 2019/0317681 A1
(43) Pub. Date: Oct. 17, 2019

(54) MEMORY SYSTEM AND METHOD OF OPERATING MEMORY CONTROLLER

(71) Applicant: SK hynix Inc., Gyeonggi-do (KR)

(72) Inventor: Jung Ae KIM, Gyeonggi-do (KR)

(21) Appl. No.: 16/178,225

(22) Filed: Nov. 1, 2018

(30) Foreign Application Priority Data
Apr. 11, 2018 (KR) 10-2018-0042291

(51) Int. Cl. G06F 3/06

(52) U.S. Cl. CPC G06F 3/0629; G06F 3/0604; G11C 16/0483; G06F 3/0673; G06F 3/0653

(57) ABSTRACT

Provided herein may be a memory system and a method of operating a memory controller. The memory system may include a memory device and a memory controller. The memory device may include a plurality of memory cells and store firmware data into the memory cells. The memory controller may control an operation of the memory device. The firmware data may include a firmware code. The memory controller may execute the firmware code based on host type information.

### CROSS-REFERENCE TO RELATED APPLICATION

The present application claims priority under 35 U.S.C. § 119(a) to Korean patent application number 10-2018-0042291, filed on Apr. 11, 2018, the entire disclosure of which is incorporated herein by reference in its entirety.

### BACKGROUND

### 1. Field of Invention

Various embodiments of the present disclosure generally relate to an electronic device. Particularly, the embodiments relate to a memory system and a method of operating a memory controller.

### 2. Description of Related Art

A memory device may have a two-dimensional (2D) structure in which strings are horizontally arranged on a semiconductor substrate. Alternatively, the memory device may have a three-dimensional (3D) structure in which strings are vertically stacked on a semiconductor substrate. As the memory device having a 2D structure is reaching its physical scaling limitations (i.e., limitations in the degree of integration), semiconductor manufacturers are producing 3D memory devices that include a plurality of memory cells vertically stacked on a semiconductor substrate to overcome the limitations of the 2D memory device. A memory controller may control the operation of the memory device.

### SUMMARY

Various embodiments of the present disclosure are directed to a memory system, which can reduce management costs for firmware data.

Various embodiments of the present disclosure are directed to a method of operating a memory controller, which can reduce management costs for firmware data.

An embodiment of the present disclosure may provide for a memory system. The memory system may include a memory device and a memory controller. The memory device may include a plurality of memory cells, and may store firmware data into the memory cells. The memory controller may control an operation of the memory device. The firmware data may include a firmware code, and the memory controller may execute the firmware code based on host type information.

In an embodiment, the firmware code may include a common code, a first code, and a second code. The memory controller may selectively execute any one of the first code and the second code based on the host type information.

In an embodiment, the firmware data may further include the host type information. The memory controller may selectively execute any one of the first code and the second code based on the host type information included in the firmware data.

In an embodiment, the memory controller may receive the host type information from a host, and may selectively execute any one of the first code and the second code based on the host type information received from the host.

In an embodiment, the memory controller may execute the common code regardless of the host type information.

An embodiment of the present disclosure may provide for a method of operating a memory controller for controlling an operation of a memory device. The method may include receiving firmware data from the memory device, identifying a type of a host from host type information included in the firmware data, and selectively executing at least one code included in the firmware data based on the identified host type.

In an embodiment, the firmware data may include a common code, a first code, and a second code. The selectively executing the at least one code may include selectively executing any one of the first code and the second code based on the identified host type.

In an embodiment, the selectively executing the at least one code may include executing the common code regardless of the identified host type.

An embodiment of the present disclosure may provide for a method of operating a memory controller for controlling an operation of a memory device. The method may include receiving host type information from a host, receiving firmware data from the memory device, and selectively executing at least one code included in the firmware data based on the host type information.

In an embodiment, the firmware data may include a common code, a first code, and a second code. The selectively executing the at least one code may include selectively executing any one of the first code and the second code based on the identified host type.

In an embodiment, the selectively executing the at least one code may include executing the common code regardless of the host type information.

An embodiment of the present disclosure may provide for a memory system. The memory system may include a memory device and a memory controller. The memory device may be configured to store firmware data. The firmware data may include a common firmware code configured to control the memory device to service common requests of hosts of different types, and dedicated firmware codes respectively configured to control the memory device to service dedicated requests of the hosts. The controller may be configured to drive, according to a type of a host to be serviced among the hosts, the common firmware code and a dedicated firmware code, which corresponds to the host to be serviced among the dedicated firmware codes, by identifying the type of the host to be serviced. The type of the host to be serviced may be represented by host type information. The common firmware code may be further configured to run the controller regardless of the types of the hosts.

In an embodiment, the firmware data may further include the host type information.

In an embodiment, the host type information may be provided from the host to be serviced.

### BRIEF DESCRIPTION OF THE DRAWINGS

FIG. 1 is a block diagram illustrating an embodiment of a memory system.

FIG. 2 is a block diagram illustrating a memory device of FIG. 1.

FIG. 3 is a diagram illustrating an embodiment of a memory cell array of FIG. 2.

FIG. 4 is a circuit diagram illustrating an example of any one memory block BLKa among memory blocks BLK1 to BLKz of FIG. 3.

FIG. 5 is a circuit diagram illustrating an example of any one memory block BLKb among the memory blocks BLK1 to BLKz of FIG. 3.

FIG. 6 is a circuit diagram illustrating an example of any one memory block BLKc among memory blocks BLK1 to BLKz included in the memory cell array 110 of FIG. 2.

FIG. 7 is a block diagram illustrating a detailed configuration of the memory system of FIG. 1.

FIGS. 8A and 8B are block diagrams illustrating a method of operating a typical memory system.

FIG. 9 is a diagram illustrating an example of firmware data applied to a memory system according to an embodiment of the present disclosure.

FIGS. 10A and 10B are diagrams illustrating a memory system and a method of operating a memory controller according to an embodiment of the present disclosure.

FIG. 11 is a diagram illustrating an example of firmware data applied to a memory system according to an embodiment of the present disclosure.

FIG. 12 is a flowchart describing a method of operating a memory controller according to an embodiment of the present disclosure.

FIG. 13 is a diagram illustrating an example of firmware data applied to a memory system according to an embodiment of the present disclosure.

FIGS. 14A and 14B are diagrams illustrating a memory system and a method of operating a memory controller according to an embodiment of the present disclosure.

FIG. 15 is a flowchart describing a method of operating a memory controller according to an embodiment of the present disclosure.

FIG. 16 is a diagram illustrating an embodiment of a memory system including the memory controller of FIG. 7.

FIG. 17 is a diagram illustrating an embodiment of a memory system including the memory device of FIG. 7.

FIG. 18 is a diagram illustrating an embodiment of a memory system including the memory device of FIG. 7.

FIG. 19 is a diagram illustrating an embodiment of a memory system including the memory device of FIG. 7.

### DETAILED DESCRIPTION

Advantages and features of the present disclosure, and methods for achieving the same will become more apparent with reference to exemplary embodiments described later in detail together with the accompanying drawings. The present disclosure is not limited to the following embodiments, but may be embodied in various other forms. That is, these embodiments are provided so that the present disclosure will be thorough and complete, and will fully convey the technical spirit of the disclosure to those skilled in the art. It is noted that reference to “an embodiment” does not necessarily mean only one embodiment, and different references to “an embodiment” are not necessarily to the same embodiment(s).

It is also noted that in this specification, “connected/coupled” refers to one component not only directly coupling another component but also indirectly coupling another component through an intermediate component. In the specification, when an element is referred to as “comprising” or “including” a component, it does not preclude another component but may further include other components unless the context clearly indicates otherwise.

The terminology used herein is for the purpose of describing particular embodiments only and is not intended to be limiting of the present invention.

The drawings are not necessarily to scale and, in some instances, proportions may have been exaggerated in order to clearly illustrate features of the embodiments.

As used herein, singular forms may include the plural forms as well and vice versa, unless the context clearly indicates otherwise.

Hereinafter, embodiments of the present disclosure will be described in detail with reference to the accompanying drawings. Reference now should be made to the drawings, in which the same reference numerals are used throughout the different drawings to designate the same or similar components. Details of well-known configurations and functions may be omitted to avoid unnecessarily obscuring the gist of the present disclosure.

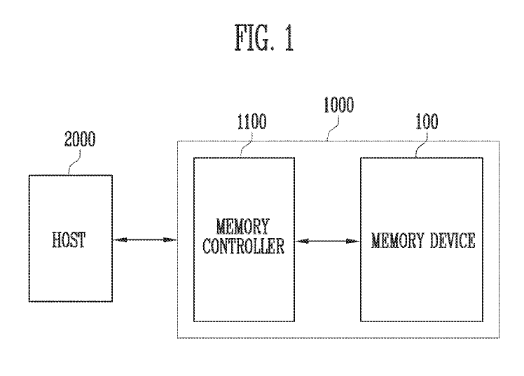

FIG. 1 is a block diagram illustrating an embodiment of a memory system 1000.

Referring to FIG. 1, the memory system 1000 includes a memory device 100 and a memory controller 1100.

The memory device 100 may operate under the control of the memory controller 1100. In detail, the memory device 100 writes data to a memory cell array in response to a write request received from the memory controller 1100. When a write command, an address, and data are received as the write request from the memory controller 1100, the memory device 100 writes data to memory cells indicated by the address.

The memory device 100 performs a read operation in response to a read request received from the memory controller 1100. When a read command and an address are received as the read request from the memory controller 1100, the memory device 100 reads data from memory cells indicated by the address, and outputs the read data to the memory controller 1100.

The memory device 100 may be embodied in various forms, such as a NAND flash memory, a vertical NAND flash memory (hereinafter referred to as ‘VNAND’), a NOR flash memory, a resistive random access memory (RRAM), a phase-change memory (PRAM), a magnetoresistive random access memory (MRAM), a ferroelectric random access memory (FRAM), or a spin transfer torque random access memory (STT-RAM). In addition, the memory device 100 according to the present disclosure may be implemented as a three-dimensional (3D) array structure. The present disclosure may also be applied not only to a flash memory device in which a charge storage layer is formed of a conductive floating gate, but also to a charge trap flash (CTF) memory device in which a charge storage layer is formed of an insulating layer.

The memory controller 1100 is coupled between the memory device 100 and a host 2000. The memory controller 1100 may interface the host 2000 with the memory device 100. The memory controller 1100 may transmit a write request or a read request to the memory device 100 under the control of the host 2000.

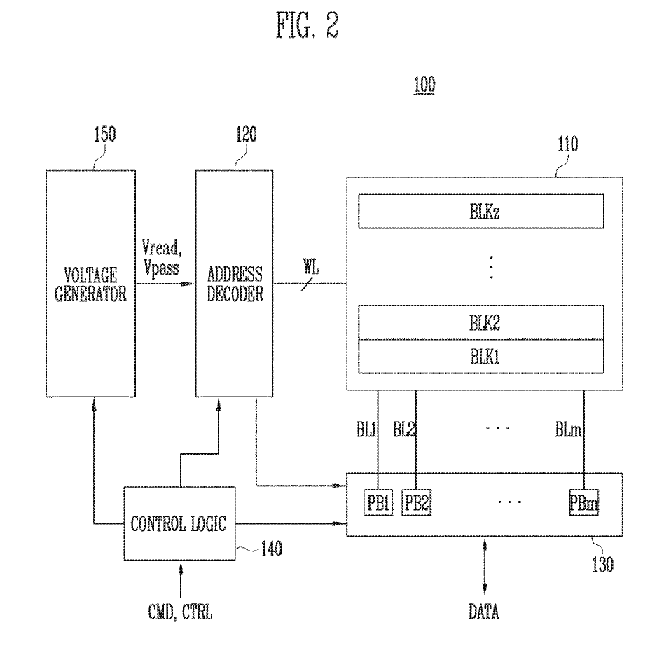

FIG. 2 is a block diagram illustrating a memory device, for example the memory device 100 of FIG. 1.

Referring to FIG. 2, the memory device 100 may include a memory cell array 110, an address decoder 120, a read and write circuit 130, a control logic 140, and a voltage generator 150.

The memory cell array 110 may include a plurality of memory blocks BLK1 to BLKz. The memory blocks BLK1 to BLKz may be coupled to the address decoder 120 through word lines WL. The memory blocks BLK1 to BLKz may be coupled to the read and write circuit 130 through bit lines BL1 to BLm. Each of the memory blocks BLK1 to BLKz may include a plurality of memory cells. In an embodiment, the plurality of memory cells may be nonvolatile memory cells, and may be implemented as nonvolatile memory cells having a vertical channel structure. The memory cell array 110 may be implemented as a memory cell array having a two-dimensional (2D) structure. In an embodiment, the memory cell array 110 may be implemented as a memory cell array having a three-dimensional (3D) structure. Each of the memory cells included in the memory cell array may store at least one bit of data. In an embodiment, each of the memory cells included in the memory cell array 110 may be a single-level cell (SLC), which stores one bit of data. In an embodiment, each of the memory cells included in the memory cell array 110 may be a multi-level cell (MLC), which stores two bits of data. In an embodiment, each of the memory cells included in the memory cell array 110 may be a triple-level cell, which stores three bits of data. In an embodiment, each of the memory cells included in the memory cell array 110 may be a quad-level cell, which stores four bits of data. In various embodiments, the memory cell array 110 may include a plurality of memory cells, each of which stores 5 or more bits of data.

The address decoder 120, the read and write circuit 130, the control logic 140, and the voltage generator 150 may operate as peripheral circuits for driving the memory cell array 110. The address decoder 120 is coupled to the memory cell array 110 through the word lines WL. The address decoder 120 may operate under the control of the control logic 140. The address decoder 120 may receive addresses through an input/output buffer (not illustrated) provided in the memory device 100.

The address decoder 120 may decode a block address, among the received addresses. The address decoder 120 selects at least one memory block based on the decoded block address. When a read voltage application operation is performed during a read operation, the address decoder 120 may apply a read voltage Vread, generated by the voltage generator 150, to a selected word line of a selected memory block, and may apply a pass voltage Vpass to remaining unselected word lines. During a program verify operation, the address decoder 120 may apply a verify voltage, generated by the voltage generator 150, to a selected word line of a selected memory block, and may apply the pass voltage Vpass to remaining unselected word lines.

The address decoder 120 may decode a column address, among the received addresses. The address decoder 120 may transmit the decoded column address to the read and write circuit 130.

The read and program operations of the memory device 100 are each performed on a page basis. Addresses received at the request of read and program operations may include a block address, a row address and a column address. The address decoder 120 may select one memory block and one word line in accordance with the block address and the row address. The column address may be decoded by the address decoder 120, and may then be provided to the read and write circuit 130.

The address decoder 120 may include a block decoder, a row decoder, a column decoder, an address buffer, etc.

The read and write circuit 130 includes a plurality of page buffers PB1 to PBm. The read and write circuit 130 may operate as a “read circuit” during a read operation of the memory cell array 110 and as a “write circuit” during a write operation thereof. The plurality of page buffers PB1 to PBm are coupled to the memory cell array 110 through the bit lines BL1 to BLm. During a read or program verify operation, in order to sense threshold voltages of the memory cells, the page buffers PB1 to PBm may continuously supply sensing current to the bit lines coupled to the memory cells while each of the page buffers PB1 to PBm senses, through a sensing node, a change in the amount of flowing current depending on the program state of a corresponding memory cell and latches it as sensing data. The read and write circuit 130 may be operated in response to page buffer control signals output from the control logic 140.

During a read operation, the read and write circuit 130 may sense data DATA stored in the memory cells and temporarily store read data DATA, and may then output data DATA to the input/output buffer (not illustrated) of the memory device 100. In an embodiment, the read and write circuit 130 may include a column select circuit or the like as well as the page buffers (or page resistors).

The control logic 140 is coupled to the address decoder 120, the read and write circuit 130, and the voltage generator 150. The control logic 140 may receive a command CMD and a control signal CTRL through the input/output buffer (not illustrated) of the memory device 100. The control logic 140 may control the overall operation of the memory device 100 in response to the control signal CTRL. The control logic 140 may output a control signal for controlling a precharge potential level at the sensing node of the plurality of page buffers PB1 to PBm. The control logic 140 may control the read and write circuit 130 to perform a read operation of the memory cell array 110.

The voltage generator 150 may generate a read voltage Vread and a pass voltage Vpass required for a read operation in response to the control signal output from the control logic 140. The voltage generator 150 may include a plurality of pumping capacitors for receiving an internal supply voltage to generate a plurality of voltages having various voltage levels, and may generate a plurality of voltages by selectively enabling the plurality of pumping capacitors under the control of the control logic 140.

The address decoder 120, the read and write circuit 130, and the voltage generator 150 may function as peripheral circuits which perform a read operation, a write operation, and an erase operation on the memory cell array 110. The peripheral circuits may perform a read operation, a write operation, and an erase operation on the memory cell array 110 under the control of the control logic 140.

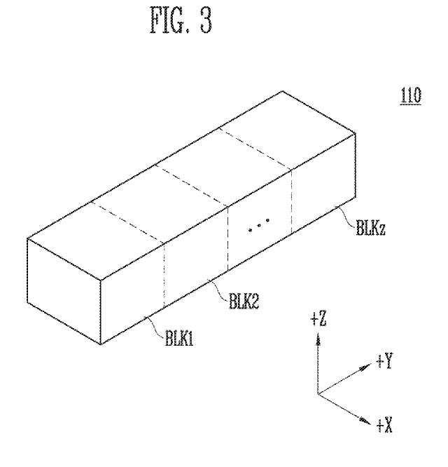

FIG. 3 is a diagram illustrating an embodiment of a memory cell array, for example the memory cell array 110 of FIG. 2.

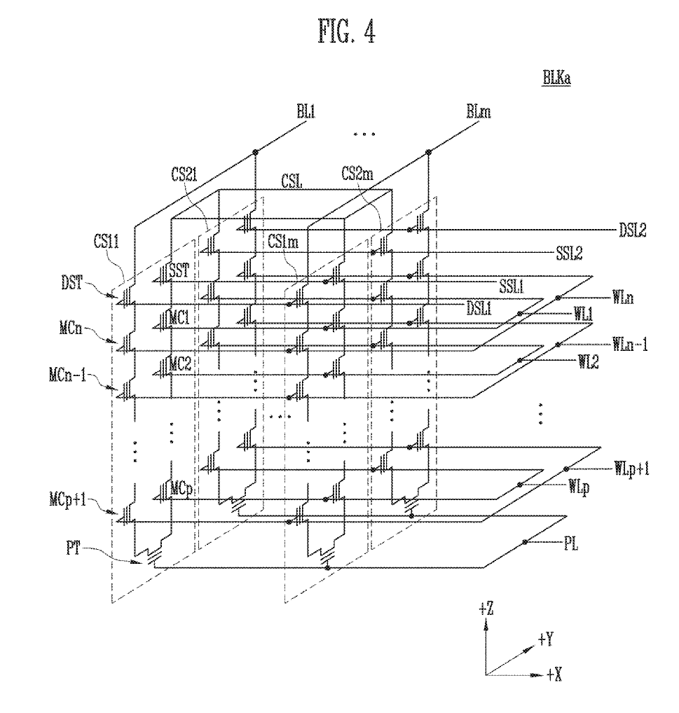

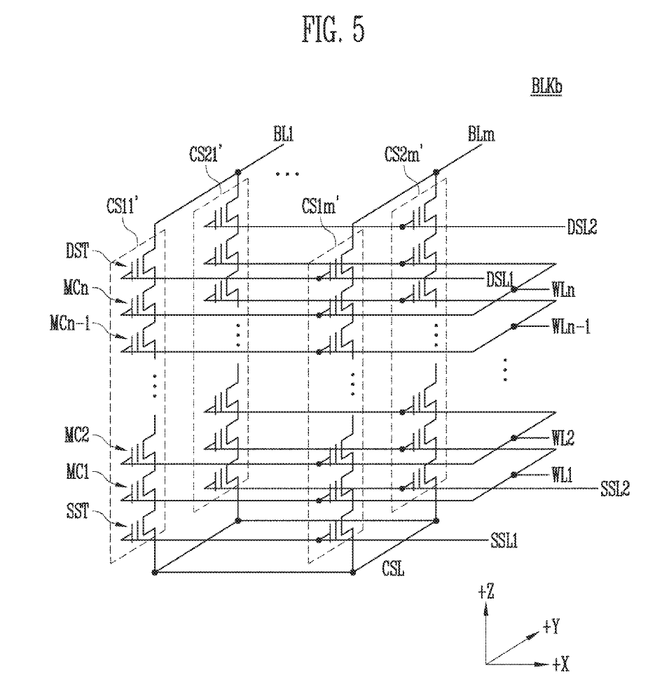

Referring to FIG. 3, the memory cell array 110 includes a plurality of memory blocks BLK1 to BLKz. Each memory block may have a two-dimensional (2D) or a three-dimensional (3D) structure. When, as shown in FIG. 3, the memory blocks have a 3D structure, each memory block includes a plurality of memory cells stacked on a substrate. Such memory cells are arranged along a positive X (+X) direction, a positive Y (+Y) direction, and a positive Z (+Z) direction. The structure of each memory block will be described in detail below with reference to FIGS. 4 and 5.

FIG. 4 is a circuit diagram illustrating an example of any one memory block BLKa among the memory blocks BLK1 to BLKz of FIG. 3.

Referring to FIG. 4, the memory block BLKa includes a plurality of cell strings CS11 to CS1m and CS21 to CS2m. In an embodiment, each of the cell strings CS11 to CS1m and CS21 to CS2m may be formed in a ‘U’ shape. In the memory block BLKa, m cell strings are arranged in a row direction (i.e., positive (+) X direction). In FIG. 4, two cell strings are illustrated as being arranged in a column direction (i.e., positive (+) Y direction). However, this illustration is made for convenience of description, and it will be understood that the number of memory cells arranged in the column direction may vary depending on design.

Each of the plurality of cell strings CS11 to CS1m and CS21 to CS2m includes at least one source select transistor SST, first to n-th memory cells MC1 to MCn, a pipe transistor PT, and at least one drain select transistor DST.

The select transistors SST and DST and the memory cells MC1 to MCn may have similar structures, respectively. In an embodiment, each of the select transistors SST and DST and the memory cells MC1 to MCn may include a channel layer, a tunneling insulating layer, a charge storage layer, and a blocking insulating layer. In an embodiment, a pillar for providing the channel layer may be provided to each cell string. In an embodiment, a pillar for providing at least one of the channel layer, the tunneling insulating layer, the charge storage layer, and the blocking insulating layer may be provided to each cell string.

The source select transistor SST of each cell string is connected between the common source line CSL and memory cells MC1 to MCp.

In an embodiment, the source select transistors of cell strings arranged in the same row are coupled to a source select line extended in a row direction, and source select transistors of cell strings arranged in different rows are coupled to different source select lines. In FIG. 4, source select transistors of cell strings CS11 to CS1m in a first row are coupled to a first source select line SSL1. The source select transistors of cell strings CS21 to CS2m in a second row are coupled to a second source select line SSL2.

In an embodiment, source select transistors of the cell strings CS11 to CS1m and CS21 to CS2m may be coupled in common to a single source select line.

The first to n-th memory cells MC1 to MCn in each cell string are coupled between the source select transistor SST and the drain select transistor DST.

The first to n-th memory cells MC1 to MCn may be divided into first to p-th memory cells MC1 to MCp and p+1-th to n-th memory cells MCp+1 to MCn. The first to p-th memory cells MC1 to MCp are sequentially arranged in a direction opposite a positive (+) Z direction and are connected in series between the source select transistor SST and the pipe transistor PT. The p+1-th to n-th memory cells MCp+1 to MCn are sequentially arranged in the +Z direction and are connected in series between the pipe transistor PT and the drain select transistor DST. The first to p-th memory cells MC1 to MCp and the p+1-th to n-th memory cells MCp+1 to MCn are coupled to each other through the pipe transistor PT. The gates of the first to n-th memory cells MC1 to MCn of each cell string are coupled to first to n-th word lines WL1 to WLn, respectively.

The gate of the pipe transistor PT of each cell string is coupled to a pipeline PL.

The drain select transistor DST of each cell string is connected between the corresponding bit line and the memory cells MCp+1 to MCn. The cell strings in a row direction are coupled to drain select lines extended in a row direction. Drain select transistors of cell strings CS11 to CS1m in the first row are coupled to a first drain select line DSL1. Drain select transistors of cell strings CS21 to CS2m in a second row are coupled to a second drain select line DSL2.

Cell strings arranged in a column direction are coupled to bit lines extended in a column direction. In FIG. 4, cell strings CS11 and CS21 in a first column are coupled to a first bit line BL1. Cell strings CS1m and CS2m in an m-th column are coupled to an m-th bit line BLm.

The memory cells coupled to the same word line in cell strings arranged in a row direction constitute a single page. For example, memory cells coupled to the first word line WL1, among the cell strings CS11 to CS1m in the first row, constitute a single page. Memory cells coupled to the first word line WL1, among the cell strings CS21 to CS2m in the second row, constitute a single additional page. Cell strings arranged in the direction of a single row may be selected by selecting any one of the drain select lines DSL1 and DSL2. A single page may be selected from the selected cell strings by selecting any one of the word lines WL1 to WLn.

In an embodiment, even bit lines and odd bit lines, instead of first to m-th bit lines BL1 to BLm, may be provided. Further, even-numbered cell strings, among the cell strings CS11 to CS1m or CS21 to CS2m arranged in a row direction, may be coupled to the even bit lines, respectively, and odd-numbered cell strings, among the cell strings CS11 to CS1m or CS21 to CS2m arranged in the row direction, may be coupled to the odd bit lines, respectively.

In an embodiment, one or more of the first to n-th memory cells MC1 to MCn may be used as dummy memory cells. For example, one or more dummy memory cells are provided to reduce an electric field between the source select transistor SST and the memory cells MC1 to MCp. Alternatively, the one or more dummy memory cells are provided to reduce an electric field between the drain select transistor DST and the memory cells MCp+1 to MCn. As more dummy memory cells are provided, the reliability of the operation of the memory block BLKa is improved, but the size of the memory block BLKa is increased. As fewer memory cells are provided, the size of the memory block BLKa is reduced, but the reliability of the operation of the memory block BLKa may be deteriorated.

In order to efficiently control the one or more dummy memory cells, each of the dummy memory cells may have a required threshold voltage. Before or after the erase operation of the memory block BLKa is performed, a program operation may be performed on all or some of the dummy memory cells. When an erase operation is performed after the program operation has been performed, the threshold voltages of the dummy memory cells control the voltages that are applied to the dummy word lines coupled to respective dummy memory cells, and thus the dummy memory cells may have required threshold voltages.

FIG. 5 is a circuit diagram illustrating an example of any one memory block BLKb among the memory blocks BLK1 to BLKz of FIG. 3.

Referring to FIG. 5, the memory block BLKb includes a plurality of cell strings CS11′ to CS1m′ and CS21′ to CS2m′. Each of the plurality of cell strings CS11′ to CS1m′ and CS21′ to CS2m′ is extended along a positive Z (+Z) direction. Each of the cell strings CS11′ to CS1m′ and CS21′ to CS2m′ includes at least one source select transistor SST, first to n-th memory cells MC1 to MCn, and at least one drain select transistor DST, which are stacked on a substrate (not illustrated) below the memory block BLKb.

The source select transistor SST of each cell string is connected between a common source line CSL and memory cells MC1 to MCn. The source select transistors of cell strings arranged in the same row are coupled to the same source select line. Source select transistors of cell strings CS11′ to CS1m′ arranged in a first row are coupled to a first source select line SSL1. Source select transistors of cell strings CS21′ to CS2m′ arranged in a second row are coupled to a second source select line SSL2. In an embodiment, source select transistors of the cell strings CS11′ to CS1m′ and CS21′ to CS2m′ may be coupled in common to a single source select line.

The first to n-th memory cells MC1 to MCn in each cell string are connected in series between the source select transistor SST and the drain select transistor DST. The gates of the first to n-th memory cells MC1 to MCn are coupled to first to n-th word lines WL1 to WLn, respectively.

The drain select transistor DST of each cell string is connected between the corresponding bit line and the memory cells MC1 to MCn. Drain select transistors of cell strings arranged in a row direction are coupled to drain select lines extended in a row direction. The drain select transistors of the cell strings CS11′ to CS1m′ in the first row are coupled to a first drain select line DSL1. The drain select transistors of the cell strings CS21′ to CS2m′ in the second row are coupled to a second drain select line DSL2.

As a result, the memory block BLKb of FIG. 5 has a circuit similar to that of the memory block BLKa of FIG. 4. That is, the pipe transistor PT included in the memory block BLKa of FIG. 4 may be excluded from each cell string in the memory block BLKb of FIG. 5.

In an embodiment, even bit lines and odd bit lines, instead of first to m-th bit lines BL1 to BLm, may be provided. Further, even-numbered cell strings, among the cell strings CS11′ to CS1m′ or CS21′ to CS2m′ arranged in a row direction, may be coupled to the even bit lines, respectively, and odd-numbered cell strings, among the cell strings CS11′ to CS1m′ or CS21′ to CS2m′ arranged in the row direction, may be coupled to the odd bit lines, respectively.

In an embodiment, one or more of the first to n-th memory cells MC1 to MCn may be used as dummy memory cells. For example, the one or more dummy memory cells are provided to reduce an electric field between the source select transistor SST and the memory cells MC1 to MCn. Alternatively, the one or more dummy memory cells are provided to reduce an electric field between the drain select transistor DST and the memory cells MC1 to MCn. As more dummy memory cells are provided, the reliability of the operation of the memory block BLKb is improved, but the size of the memory block BLKb is increased. As fewer memory cells are provided, the size of the memory block BLKb is reduced, but the reliability of the operation of the memory block BLKb may be deteriorated.

In order to efficiently control the one or more dummy memory cells, each of the dummy memory cells may have a required threshold voltage. Before or after the erase operation of the memory block BLKb is performed, a program operation may be performed on all or some of the dummy memory cells. When an erase operation is performed after the program operation has been performed, the threshold voltages of the dummy memory cells control the voltages that are applied to the dummy word lines coupled to respective dummy memory cells, and thus the dummy memory cells may have required threshold voltages.

FIG. 6 is a circuit diagram illustrating an example of any one memory block BLKc among the memory blocks BLK1 to BLKz included in the memory cell array 110 of FIG. 2.

Referring to FIG. 6, the memory block BLKc includes a plurality of cell strings CS1 to CSm. The plurality of cell strings CS1 to CSm may be coupled to a plurality of bit lines BL1 to BLm, respectively. Each of the cell strings CS1 to CSm includes at least one source select transistor SST, first to n-th memory cells MC1 to MCn, and at least one drain select transistor DST.

The select transistors SST and DST and the memory cells MC1 to MCn may have similar structures. In an embodiment, each of the select transistors SST and DST and the memory cells MC1 to MCn may include a channel layer, a tunneling insulating layer, a charge storage layer, and a blocking insulating layer. In an embodiment, a pillar for providing the channel layer may be provided in each cell string. In an embodiment, a pillar for providing at least one of the channel layer, the tunneling to insulating layer, the charge storage layer, and the blocking insulating layer may be provided in each cell string.

The source select transistor SST of each cell string is coupled between a common source line CSL and the memory cells MC1 to MCn.

The first to n-th memory cells MC1 to MCn in each cell string are coupled between the source select transistor SST and the drain select transistor DST.

The drain select transistor DST of each cell string is coupled between the corresponding bit line and the memory cells MC1 to MCn.

The memory cells coupled to the same word line may constitute a single page. The cell strings CS1 to CSm may be selected by selecting the drain select line DSL. One page may be selected from the selected cell strings by selecting any one of the word lines WL1 to WLn.

In other embodiments, even bit lines and odd bit lines may be provided instead of the first to m-th bit lines BL1 to BLm. Among the cell strings CS1 to CSm, even-numbered cell strings may be coupled to the even bit lines, respectively, and odd-numbered cell strings may be coupled to the odd bit lines, respectively.

As illustrated in FIGS. 3 to 5, the memory cell array 110 of the memory device 100 may be implemented as a memory cell array having a 3D structure. Further, as illustrated in FIG. 6, the memory cell array 110 of the memory device 100 may be implemented as a memory cell array having a 2D structure.

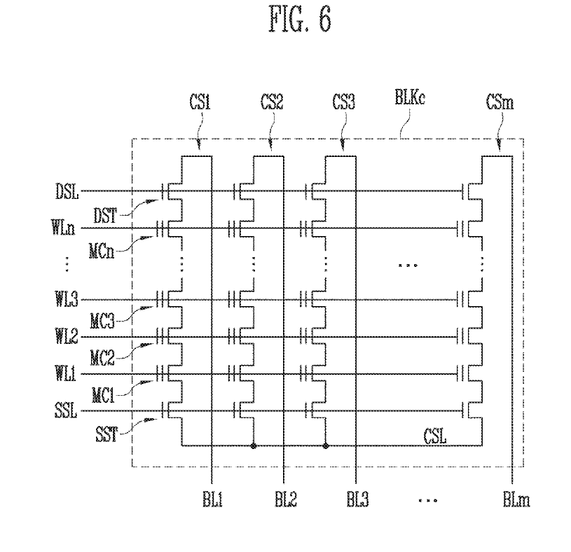

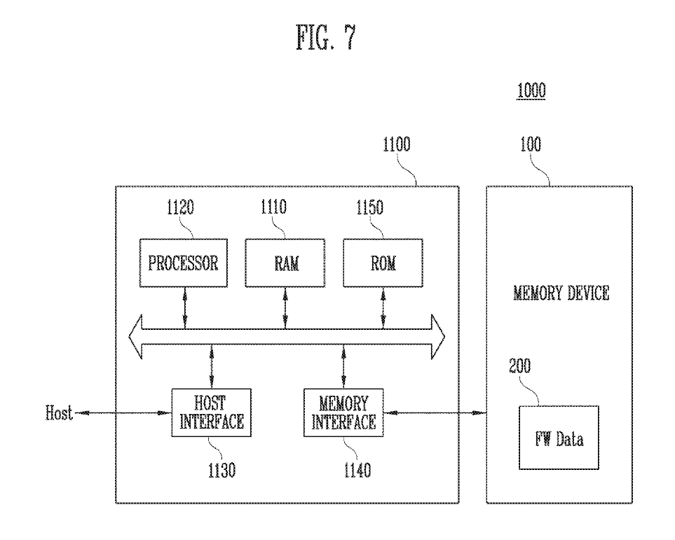

FIG. 7 is a block diagram illustrating a detailed configuration of a memory system, for example the memory system 1000 of FIG. 1.

Referring to FIG. 7, the memory system 1000 includes a memory device 100 and a memory controller 1100. The memory controller 1100 is coupled to a host (e.g., the host 2000 shown in FIG. 1) and the memory device 100. The memory controller 1100 may access the memory device 100 in response to a request from the host. For example, the memory controller 1100 may control read, write, erase, and background operations of the memory device 100. The memory controller 1100 may provide an interface between the memory device 100 and the host.

The memory controller 1100 includes a random access memory (RAM) 1110, a processor 1120, a host interface 1130, a memory interface 1140, and a read-only memory (ROM) 1150. The RAM 1110 may be used as at least one of a working memory of the processor 1120, a cache memory between the memory device 100 and the host, and a buffer memory between the memory device 100 and the host. The processor 1120 may control the overall operation of the memory controller 1100. In addition, the memory controller 1100 may temporarily store program data provided from the host during a write operation.

The host interface 1130 includes a protocol for performing data exchange between the host and the memory controller 1100. By way of example and not limitation, the memory controller 1100 may communicate with the host through at least one of various interface protocols, such as a universal serial bus (USB) protocol, a multimedia card (MMC) protocol, a peripheral component interconnection (PCI) protocol, a PCI-express (PCI-e or PCIe) protocol, an advanced technology attachment (ATA) protocol, a serial-ATA protocol, a parallel-ATA protocol, a small computer small interface (SCSI) protocol, an enhanced small disk interface (ESDI) protocol, an integrated drive electronics (IDE) protocol, and a private protocol.

The memory interface 1140 interfaces with the memory device 100. For example, the memory interface may include a NAND interface or NOR interface.

The memory controller 1100 may run firmware FW for controlling the memory device 100. In detail, when the memory system 1000 is turned on, a ROM code stored in the ROM 1150 is loaded into the RAM 1110. The processor 1120 controls the memory device 100 so that firmware data 200 (denoted as “FW Data”) stored in the memory device 100 is read by executing the ROM code loaded into the RAM 1110.

The firmware data 200 read by the memory device 100 is transferred to the memory controller 1100. The firmware data 200 may include firmware codes. The firmware codes may be loaded into the RAM 1110. When the firmware codes are loaded into the RAM 1110, the processor 1120 may execute the loaded firmware codes. As the firmware codes are executed by the processor 1120, the initial startup of the memory system 1000 is completed.

In an embodiment, the processor 1120 may read a bootloader code (not illustrated) stored in the memory device 100 by executing the ROM code. The bootloader code may be stored separately from the firmware data 200. The read bootloader code may be loaded into the RAM 1110. The processor 1120 may control the memory device 100 so that firmware data 200 stored in the memory device 100 is read by executing the loaded bootloader code.

In accordance with the embodiment of the present disclosure, the memory device 100 stores firmware data 200 including host type information. Meanwhile, the memory controller 1100 may execute the firmware codes, included in the firmware data, based on the host type information. Accordingly, management costs for the firmware data may be reduced.

The memory controller 1100 and the memory device 100 may be integrated into a single semiconductor device. In an embodiment, the memory controller 1100 and the memory device 100 may be integrated into a single semiconductor device to form a memory card. By way of example and not limitation, the memory controller 1100 and the memory device 100 may be integrated into a single semiconductor device to form a memory card, such as a personal computer memory card international association (PCMCIA), a compact flash card (CF), a smart media card (e.g., SM or SMC), a memory stick, a multimedia card (e.g., MMC, a reduced-size multimedia card (RS-MMC) or a micro-size version of MMC (MMCmicro)), a SD card (e.g., SD, miniSD, microSD, or secure digital high capacity (SDHC)), or a universal flash storage (UFS).

The memory controller 1100 and the memory device 100 may be integrated into a single semiconductor device to form a solid state drive (SSD). The SSD includes a storage device configured to store data in a semiconductor memory. When the memory system 1000 is used as the SSD, the operation speed of the host coupled to the memory system 1000 may be phenomenally improved.

In other embodiments, the memory system 1000 may be provided as one of various elements of an electronic device such as a computer, a ultra mobile PC (UMPC), a workstation, a net-book, a personal digital assistants (PDA), a portable computer, a web tablet, a wireless phone, a mobile phone, a smart phone, an e-book, a portable multimedia player (PMP), a game console, a navigation device, a black box, a digital camera, a 3-dimensional television, a digital audio recorder, a digital audio player, a digital picture recorder, a digital picture player, a digital video recorder, a digital video player, a device capable of transmitting/receiving information in an wireless environment, one of various devices for forming a home network, one of various electronic devices for forming a computer network, one of various electronic devices for forming a telematics network, an RFID device, one of various elements for forming a computing system, or the like.

In an exemplary embodiment, the memory device 100 or the memory system 1000 may be embedded in various types of packages. By way of example and not limitation, the memory device 100 or the memory system 1000 may be packaged in a type such as Package on Package (PoP), Ball grid arrays (BGAs), Chip scale packages (CSPs), Plastic Leaded Chip Carrier (PLCC), Plastic Dual In Line Package (PDIP), Die in Waffle Pack, Die in Wafer Form, Chip On Board (COB), Ceramic Dual In Line Package (CERDIP), Plastic Metric Quad Flat Pack (MQFP), Thin Quad Flatpack (TQFP), Small Outline Integrated Circuit (SOIC), Shrink Small Outline Package (SSOP), Thin Small Outline Package (TSOP), Thin Quad Flatpack (TQFP), System In Package (SIP), Multi-Chip Package (MCP), Wafer-level Fabricated Package (WFP), Wafer-Level Processed Stack Package (WSP), or the like.

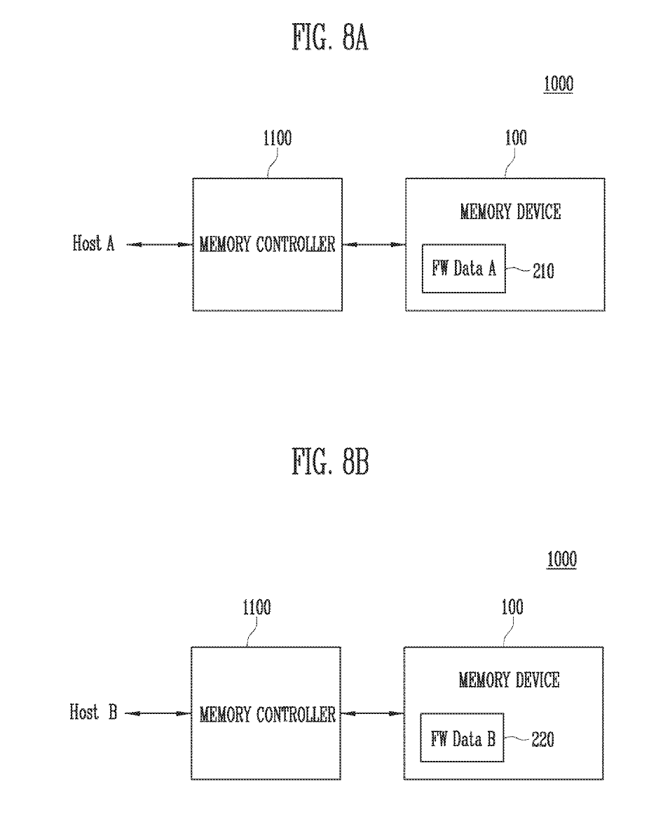

FIGS. 8A and 8B are block diagrams illustrating a method of operating a typical memory system.

Referring to FIG. 8A, a memory controller 1100 communicates with host A. Meanwhile, the memory controller 1100 has to execute a firmware code corresponding to host A to perform an operation suitable for host A. Accordingly, firmware data A 210 corresponding to host A is stored in the memory device 100. The firmware data A 210 may be firmware data corresponding to host A.

Referring to FIG. 8B, the memory controller 1100 communicates with host B. The memory controller 1100 has to execute a firmware code corresponding to host B to perform an operation suitable for host B. Accordingly, firmware data B 220 corresponding to host B is stored in the memory device 100. The firmware data B 220 may be firmware data corresponding to host B.

As illustrated in FIGS. 8A and 8B, when the type of host varies, the firmware code to be executed by the memory controller 1100 may also vary in accordance with the varying host type. For example, a function specifically required according to the type of host may be implemented by the firmware code. Accordingly, the memory device 100 should store different pieces of firmware data, for example the firmware data A 210 and the firmware data B 220, depending on the host Host A or Host B coupled thereto. This means that the pieces of firmware data have to be separately prepared and managed for respective hosts. This configuration increases management costs for firmware data.

In accordance with the embodiment of the present disclosure, common firmware data is stored in the memory device regardless of the type of host, and firmware codes included in the firmware data are selectively executed based on the host type information. Accordingly, there is no need to separately generate and manage pieces of firmware data for respective hosts, and it is possible to reduce management costs for firmware data.

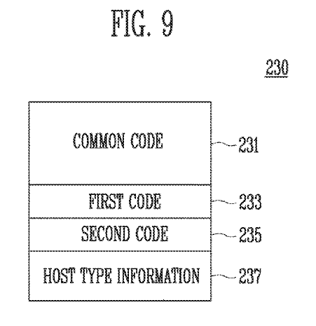

FIG. 9 is a diagram illustrating an example of firmware data applied to a memory system, for example the memory system 1000, according to an embodiment of the present disclosure.

Referring to FIG. 9, firmware data 230 may include a common code 231, a first code 233, a second code 235, and host type information 237. The common code 231 may be a firmware code that is executed in common regardless of the type of host. The first code 233 may be a firmware code that is executed when the memory controller 1100 is coupled to a host A. Meanwhile, the second code 235 may be a firmware code that is executed when the memory controller 1100 is coupled to a host B. That is, the common code 231, the first code 233, and the second code 235 may form firmware codes included in the firmware data 230. The firmware data 230 may include the firmware codes 231 to 235 and the host type information 237.

The host type information 237 may be information indicating the type of the host to which the memory controller 1100 is to be coupled. For example, the host type information 237 may be predetermined. The type of host may vary according to a data processing system to which the memory system 1000 is to be applied. The data processing system includes the host of various types and the memory system 1000. For example, when the memory system 1000 is mounted on the data processing system including host A, a piece of information indicating host A may be contained in the host type information 237. In an embodiment, when the memory system 1000 is mounted on the data processing system including host B, a piece of information indicating host B may be contained in the host type information 237. Requirement for the memory system 1000 may vary according to the data processing system, and thus the firmware codes to be executed by the memory controller 1100 may also vary.

Accordingly, the firmware data 230 stored in the memory device of the memory system 1000 includes the same firmware codes 231, 233, and 235 even if the host changes, but includes different pieces of host type information 237 depending on the type of host. Consequently, only the host type information 237 is varied, and thus the firmware codes that are executed on the memory controller 1100 may also be varied. Accordingly, the management costs for the firmware codes or firmware data may be reduced.

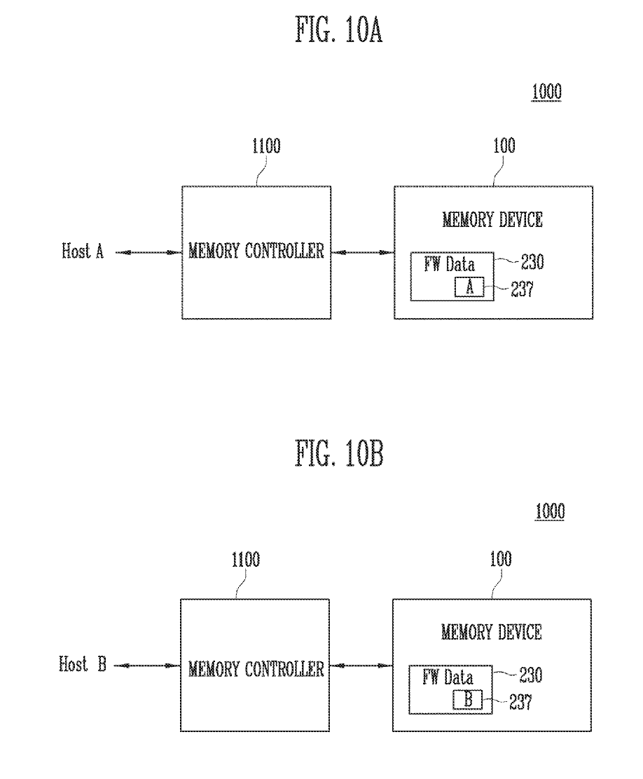

FIGS. 10A and 10B are diagrams illustrating a memory system, for example the memory system 1000 of FIG. 1, and a method of operating a memory controller, for example the memory controller 1100 of FIG. 1, according to an embodiment of the present disclosure.

Referring to FIGS. 10A and 10B, a memory system 1000 includes a memory controller 1100 and a memory device 100. The memory device 100 stores firmware data 230. The firmware data 230 may be firmware data 230 illustrated in FIG. 9. For convenience of illustration, only host type information 237, among the various components of the firmware data 230 (e.g., common code 231, first code 233, second code 235), is illustrated.

Referring to FIG. 10A, the memory system 1000 is coupled to a host A. This means that the memory system 1000 is mounted on the data processing system including the host A. Therefore, the host type information 237 of the firmware data 230 may indicate the host A.

When the memory system 1000 is started, the memory controller 1100 receives the firmware data 230 from the memory device 100. Meanwhile, the memory controller 1100 identifies the host A from the host type information 237 included in the received firmware data 230. Accordingly, the memory controller 1100 may execute a firmware code corresponding to the host A, among firmware codes included in the firmware data 230. For example, the memory controller 1100 may execute the common code 231 and the first code 233 illustrated in FIG. 9. In this case, the second code 235, which is a firmware code corresponding to host B, is not executed by the memory controller 1100 illustrated in FIG. 10A. That is, of the firmware data 230 of FIG. 9, the common code 231 and the first code 233 may be firmware codes that are executed by the memory controller 1100 coupled to the host A.

Meanwhile, referring to FIG. 10B, the memory system 1000 is coupled to a host B. This means that the memory system 1000 is mounted on the data processing system including the host B. Therefore, the host type information 237 of the firmware data 230 may indicate the host B.

When the memory system 1000 is started, the memory controller 1100 receives the firmware data 230 from the memory device 100. Meanwhile, the memory controller 1100 identifies the host B from the host type information 237 included in the received firmware data 230. Accordingly, the memory controller 1100 may execute a firmware code corresponding to the host B, among firmware codes included in the firmware data 230. For example, the memory controller 1100 may execute the common code 231 and the second code 235 illustrated in FIG. 9. In this case, the first code 233, which is a firmware code corresponding to host A, is not executed by the memory controller 1100 illustrated in FIG. 10B. That is, of the firmware data 230 of FIG. 9, the common code 231 and the second code 235 may be firmware codes that are executed by the memory controller 1100 coupled to the host B.

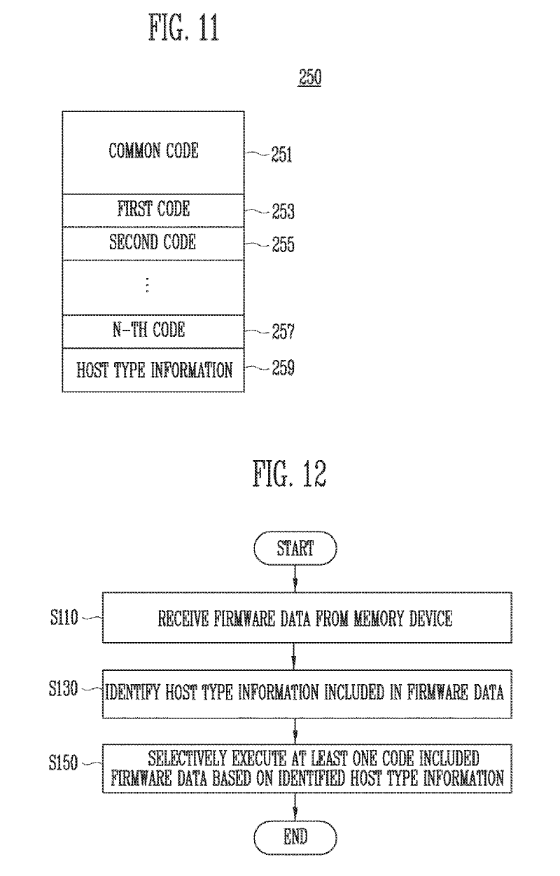

FIG. 11 is a diagram illustrating an example of firmware data applied to a memory system, for example the memory system 1000 of FIG. 1, according to an embodiment of the present disclosure.

Referring to FIG. 11, firmware data 250 including firmware codes respectively corresponding to N host types is illustrated. That is, the firmware data 250 may include a common code 251, first to N-th codes 253, 255, . . . , 257, and host type information 259. The common code 251 may be a firmware code that may be executed in common by memory controllers coupled to N types of hosts. When a data processing system includes one or more memory controllers, N numbers of different hosts and a memory device, the memory device may store the firmware data 250. The first to N-th codes 253, 255, . . . , 257 may be firmware codes that may be selectively executed by the memory controllers for the hosts. When comparing the embodiments described in FIGS. 9 and 11, it can be seen that the firmware data 230 of FIG. 9 includes firmware codes corresponding to two types of hosts, that is, Host A and Host B, but the firmware data 250 of FIG. 11 includes firmware codes corresponding to N types of hosts.

FIG. 12 is a flowchart describing a method of operating a memory controller, for example the memory controller 1100, according to an embodiment of the present disclosure.

The method of operating the memory controller 1100 according to an embodiment of the present disclosure as shown in FIG. 12 will be described with references to FIGS. 9, 10A and 10B. First, the memory controller 1100 receives firmware data 230 from the memory device 100 at step S110. The memory controller 1100 then identifies a type of the host coupled to the memory controller 1100 from the host type information 237 included in the firmware data 230 at step S130. At step S150, the memory controller 1100 selectively executes at least one code, for example between the first code 233 or the second code 235, included in the firmware data 230 based on the identified host type.

First, the step S110 of FIG. 12 is performed when the memory system 1000 is started. As described above, when the memory system 1000 is started, a ROM code stored in the ROM 1150 of FIG. 7 is executed by the processor 1120, and thus firmware data 230, stored in the memory device 100, is read and transferred to the memory controller 1100.

At step S130, the memory controller 1100 identifies the type of the host coupled to the memory controller 1100 from the host type information 237 included in the received firmware data 230. Accordingly, whether the memory controller 1100 is coupled to host A or host B may be determined.

At step S150, the memory controller 1100 may selectively execute any one of the first code 233 and the second code 235 of FIG. 9, based on the identified host type, i.e., whether the host is host A or host B. Meanwhile, the memory controller 1100 may execute the common code 231 of FIG. 9 regardless of the host type information 237. As a result, when the host type information 237 indicates host A, the memory controller 1100 executes the common code 231 and the first code 233 at step S150. In contrast, when the host type information 237 indicates host B, the memory controller 1100 executes the common code 231 and the second code 235 at step S150.

FIG. 13 is a diagram illustrating an example of firmware data applied to a memory system, for example the memory system 1000 of FIG. 1, according to an embodiment of the present disclosure.

Referring to FIG. 13, firmware data 270 including firmware codes respectively corresponding to N host types is illustrated. That is, the firmware data 270 may include a common code 271 and first to N-th codes 273, 275, . . . , 277. Unlike the firmware data 230 and 250 illustrated in FIGS. 9 and 11 respectively, the firmware data 270 illustrated in FIG. 13 does not include the host type information. That is, the host type information may be transferred from the outside of the memory system 1000 and may not be stored in the memory device 100.

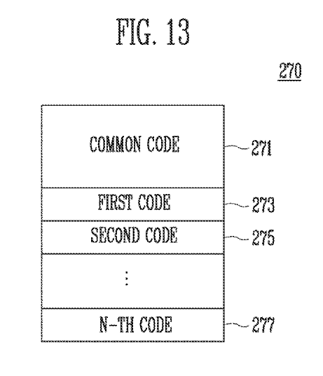

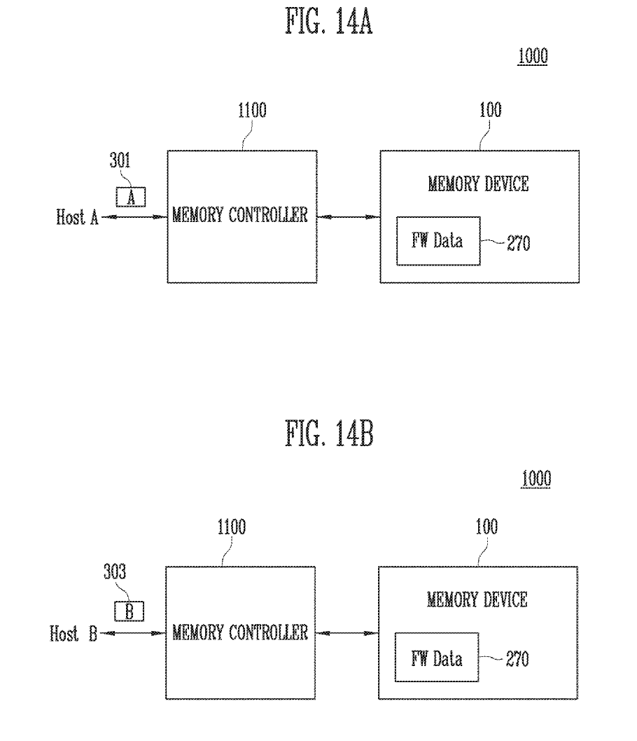

FIGS. 14A and 14B are diagrams illustrating a memory system, for example the memory system 1000 of FIG. 1, and a method of operating a memory controller, for example the memory controller 1100 of FIG. 1, according to an embodiment of the present disclosure.

Referring to FIGS. 14A and 14B, a memory system 1000 includes a memory controller 1100 and a memory device 100. The memory device 100 stores firmware data 270. The firmware data 270 may be firmware data 270 illustrated in FIG. 13. As described above with reference to FIG. 13, the firmware data 270 does not include host type information.

Referring to FIG. 14A, the memory system 1000 is coupled to a host A. Meanwhile, when the memory system 1000 is started, the memory system 1000 may communicate with the host A. At this step, the host A may transfer host type information 301 to the memory controller 1100. The host type information 301 may contain information indicating that the host A is coupled to the memory controller 1100.

The memory controller 1100 may receive the firmware data 270 from the memory device 100. Meanwhile, the memory controller 1100 may execute firmware codes corresponding to the host A, among firmware codes included in the firmware data 270, based on the host type information 301 received from the host A. For example, the memory controller 1100 may execute the common code 271 and the first code 273 illustrated in FIG. 13. In this case, second to N-th codes 275 to 277 are not executed by the memory controller 1100 illustrated in FIG. 14A. That is, of the firmware data 270 illustrated in FIG. 13, the common code 271 and the first code 273 may be firmware codes that are executed by the memory controller 1100 coupled to the host A.

Referring to FIG. 14B, the memory system 1000 is coupled to a host B. Meanwhile, when the memory system 1000 is started, the memory system 1000 may communicate with the host B. At this step, the host B may transfer host type information 303 to the memory controller 1100. The host type information 303 may contain information indicating that the host B is coupled to the memory controller 1100.

The memory controller 1100 may receive the firmware data 270 from the memory device 100. Meanwhile, the memory controller 1100 may execute firmware codes corresponding to the host B, among firmware codes included in the firmware data 270, based on the host type information 303 received from the host B. For example, the memory controller 1100 may execute the common code 271 and the second code 275 illustrated in FIG. 13. In this case, the first to N-th codes 273 to 277 except the second code 275 are not executed by the memory controller 1100 illustrated in FIG. 14A. That is, of the firmware data 270 illustrated in FIG. 13, the common code 271 and the second code 275 may be firmware codes that are executed by the memory controller 1100 coupled to the host B.

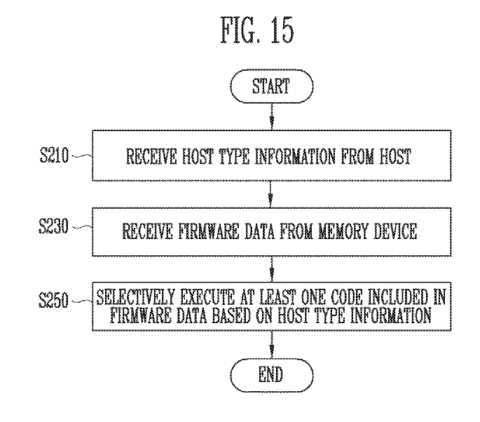

FIG. 15 is a flowchart describing a method of operating a memory controller, for example the memory controller 1100 of FIG. 1, according to an embodiment of the present disclosure.

The method of operating the memory controller 1100 according to an embodiment of the present disclosure as described in FIG. will be described with reference to FIGS. 13, 14A, and 14B. At step S210, the memory controller 1100 receives host type information 301 or 303 from the host and identifies a type of the host coupled to the memory controller 1100 from the host type information 301 or 303. The memory controller 1100 then receives firmware data 270 from the memory device 100 at step S230. At step S250, the memory controller 1100 selectively executes at least one code (e.g., at least one of codes among the first code 273 to n-th code 277) included in the firmware data 270 based on the identified host type.

First, the step S210 of FIG. 15 is performed when the memory system 1000 is started. As described above, when the memory system 1000 is started, the host type information 301 or 302 may be received from the host. The received host type information 301 or 303 may be temporarily stored in the memory controller 1100. Therefore, the memory controller 1100 identifies the type of the host coupled to the memory controller 1100 from the host type information 301 or 302. Accordingly, whether the memory controller 1100 is coupled to host A or host B may be determined.

Meanwhile, at step S230, the firmware data 270 stored in the memory device 100 may be read and transferred to the memory controller 1100. The firmware data 270 received at step S230 may not include host type information.

At step S250, the memory controller 1100 may selectively execute any one of the first to N-th codes 273 to 277 of FIG. 13, based on the identified host type. Meanwhile, the memory controller 1100 may execute the common code 271 of FIG. 13 regardless of the received host type information 301 or 303. As a result, when the host type information 301 indicates host A, the memory controller 1100 executes the common code 271 and the first code 273 at step S250. In contrast, when the host type information 303 indicates host B, the memory controller 1100 executes the common code 271 and the second code 275 at step S250.

As described above, in accordance with embodiments of the present disclosure, the memory device 100 may store pieces of firmware data 230, 250 or 270, which includes the same firmware codes regardless of the type of host. Meanwhile, the memory controller 1100 executes codes corresponding to a host type, among firmware codes, based on the host type information 237, 259, 301, or 303. Meanwhile, regardless of the host type information, the memory controller 1100 executes the common code 231, 251 or 271, among the firmware codes. According to an embodiment, the host type information may be included in the firmware data 230 or 250, or may be received from the host. Accordingly, there is no need to separately generate and manage pieces of firmware data for respective hosts, and it is possible to reduce management costs for firmware data.

FIG. 16 is a diagram illustrating an embodiment of a memory system including the memory controller of FIG. 7.

Referring to FIG. 16, a memory system 30000 may be implemented as a cellular phone, a smart phone, a tablet PC, a personal digital assistant (PDA) or a wireless communication device.

The memory system 30000 may include a memory device 100 and a memory controller 1100 that is capable of controlling the operation of the memory device 100. The memory controller 1100 may control a data access operation of the memory device 100, for example, a program operation, an erase operation or a read operation, under the control of a host 2000.

Data programmed to the memory device 100 may be output via a display 3200 under the control of the memory controller 1100.

A radio transceiver 3300 may exchange radio signals through an antenna ANT. For example, the radio transceiver 3300 may convert radio signals received through the antenna ANT into signals that may be processed by the host 2000. Therefore, the host 2000 may process the signals output from the radio transceiver 3300, and may transmit the processed signals to the memory controller 1100 or the display 3200. The memory controller 1100 may transmit the signals, processed by the host 2000, to the memory device 100. Further, the radio transceiver 3300 may convert signals output from the host 2000 into radio signals, and output the converted radio signals to an external device through the antenna ANT. An input device 3400 may be used to input a control signal for controlling the operation of the host 2000 or data to be processed by the host 2000. The input device 3400 may be implemented as a pointing device such as a touch pad or a computer mouse, a keypad or a keyboard. The host 2000 may control the operation of the display 3200 so that data from the memory controller 1100, data from the radio transceiver 3300, or data from the input device 3400 is output via the display 3200.

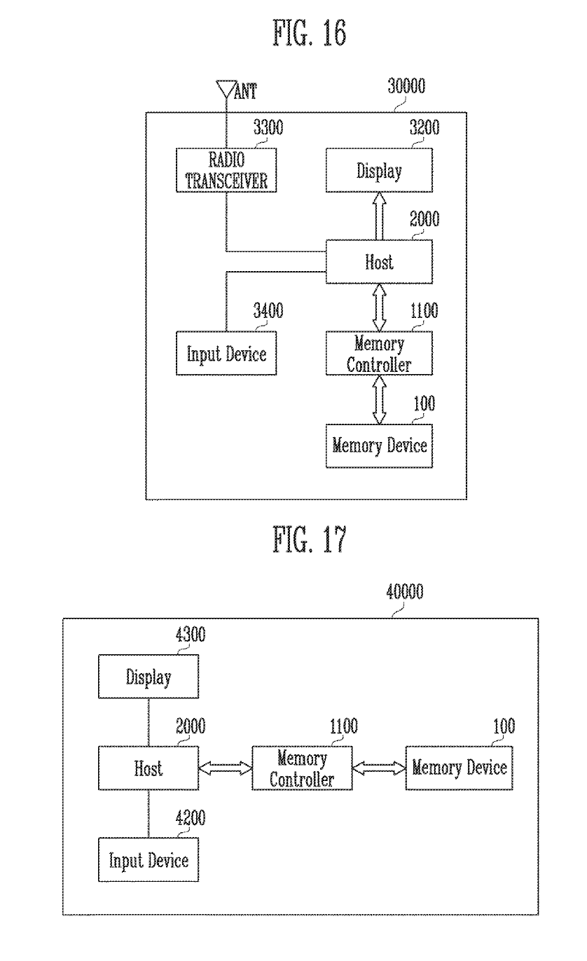

FIG. 17 is a diagram illustrating an embodiment of a memory system including the memory device of FIG. 7.

Referring to FIG. 17, a memory system 40000 may be embodied in a personal computer (PC), a tablet PC, a net-book, an e-reader, a personal digital assistant (PDA), a portable multimedia player (PMP), an MP3 player, or an MP4 player.

The memory system 40000 may include a memory device 100 and a memory controller 1100 that is capable of controlling a data processing operation of the memory device 100.

Further, a host 2000 may output data, stored in the memory device 100, via a display 4300 according to data input through an input device 4200. For example, the input device 4200 may be implemented as a pointing device such as a touch pad or a computer mouse, a keypad or a keyboard.

The host 2000 may control the overall operation of the memory system 40000, and may control the operation of the memory controller 1100.

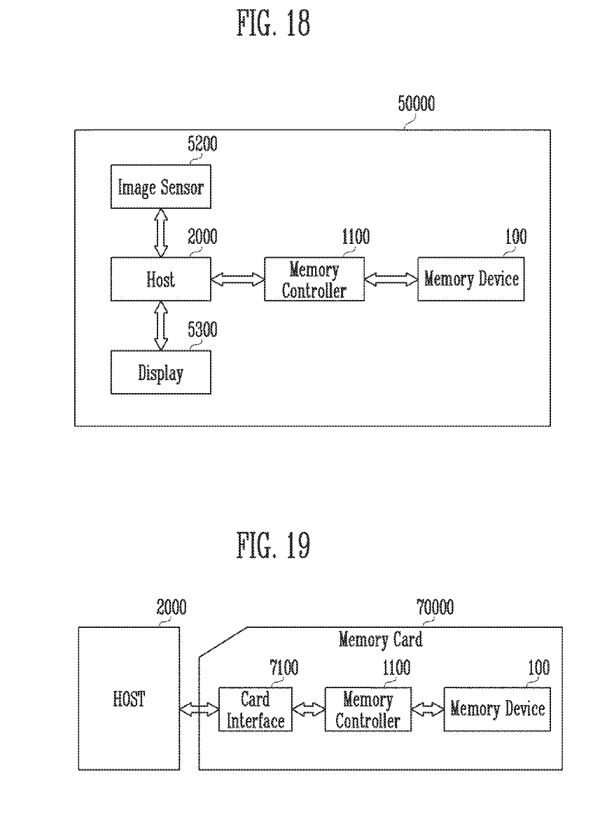

FIG. 18 is a diagram illustrating an embodiment of a memory system including the memory device of FIG. 7.

Referring to FIG. 18, a memory system 50000 may be embodied in an image processing device, e.g., a digital camera, a mobile phone provided with a digital camera, a smartphone provided with a digital camera, or a tablet PC provided with a digital camera.

The memory system 50000 may include a memory device 100 and a memory controller 1100 that is capable of controlling a data processing operation of the memory device 100, e.g., a program operation, an erase operation or a read operation.

An image sensor 5200 of the memory system 50000 may convert an optical image into digital signals, and the converted digital signals may be transmitted to a host 2000. Under the control of the host 2000, the converted digital signals may be output via a display 5300 or stored in the memory device 100 through the memory controller 1100. Further, data stored in the memory device 100 may be output via the display 5300 under the control of the host 2000.

FIG. 19 is a diagram illustrating an embodiment of a memory system including the memory device of FIG. 7.

Referring to FIG. 19, the memory system may include a memory card 70000.

The memory card 70000 may be implemented as a smart card. The memory card 70000 may include a memory device 100, a memory controller 1100, and a card interface 7100.

The memory controller 1100 may control data exchange between the memory device 100 and the card interface 7100. In an embodiment, the card interface 7100 may be, but is not limited to, a secure digital (SD) card interface or a multi-media card (MMC) Interface. Further, the card interface 7100 may interface data exchange between the host 2000 and the memory controller 1100 according to a protocol of the host 2000. In an embodiment, the card interface 7100 may support a universal serial bus (USB) protocol and an interchip (IC)-USB protocol. Here, the card interface 7100 may refer to hardware capable of supporting a protocol which is used by the host 2000, software installed in the hardware, or a signal transmission method performed by the hardware.

In accordance with an embodiment of the present disclosure, there can be provided a memory system, which can reduce management costs for firmware data.

In accordance with an embodiment of the present disclosure, there can be provided a method of operating a memory controller, which can reduce management costs for firmware data.

While the exemplary embodiments of the present disclosure have been disclosed for illustrative purposes, those skilled in the art will appreciate that various modifications, additions and substitutions are possible. Therefore, the scope of the present disclosure must be defined by the appended claims and equivalents of the claims rather than by the description preceding them.

What is claimed is:

1. A memory system, comprising:
a memory device including a plurality of memory cells and configured to store firmware data into the memory cells; and
a memory controller configured to control an operation of the memory device,
wherein the firmware data comprises a firmware code, and
wherein the memory controller is configured to execute the firmware code based on host type information.

2. The memory system according to claim 1, wherein:
the firmware code comprises a common code, a first code, and a second code, and
the memory controller selectively executes any one of the first code and the second code based on the host type information.

3. The memory system according to claim 2, wherein the firmware data further comprises the host type information.

4. The memory system according to claim 2, wherein the memory controller receives the host type information from a host.

5. The memory system according to claim 2, wherein the memory controller executes the common code regardless of the host type information.

6. A method of operating a memory controller for controlling an operation of a memory device, the method comprising:
receiving firmware data from the memory device;
identifying a type of a host from host type information included in the firmware data; and
selectively executing at least one code included in the firmware data based on the identified host type.

7. The method according to claim 6, wherein:
the firmware data comprises a common code, a first code, and a second code, and
the selectively executing includes selectively executing any one of the first code and the second code based on the identified host type.

8. The method according to claim 7, wherein the selectively executing includes executing the common code regardless of the identified host type.

9. A method of operating a memory controller for controlling an operation of a memory device, the method comprising:
receiving host type information from a host;
receiving firmware data from the memory device; and
selectively executing at least one code included in the firmware data based on the host type information.

10. The method according to claim 9, wherein:
the firmware data comprises a common code, a first code, and a second code, and
the selectively executing includes selectively executing any one of the first code and the second code based on the host type information.

11. The method according to claim 10, wherein the selectively executing includes executing the common code regardless of the host type information.

12. A memory system comprising:
a memory device configured to store firmware data including:
a common firmware code configured to control the memory device to service common requests of hosts of different types; and
dedicated firmware codes respectively configured to control the memory device to service dedicated requests of the hosts; and
a controller configured to drive, according to a type of a host to be serviced among the hosts, the common firmware code and a dedicated firmware code, which corresponds to the host to be serviced among the dedicated firmware codes, by identifying the type of the host to be serviced,
wherein the type of the host to be serviced is represented by host type information, and
wherein the common firmware code is further configured to run the controller regardless of the types of the hosts.

13. The memory system of claim 12, wherein the firmware data further includes the host type information.

14. The memory system of claim 12, wherein the host type information is provided from the host to be serviced.
